(19) United States
(12) Patent Application Publication
(10) Pub. No.: US 2014/0070398 A1
(43) Pub. Date: Mar. 13, 2014

(54) POWER SEMICONDUCTOR DEVICE AND METHOD OF MANUFACTURING THE SAME

(71) Applicant: MITSUBISHI ELECTRIC CORPORATION, Tokyo (JP)

(72) Inventors: Noboru MIYAMOTO, Tokyo (JP); Naoki YOSHIMATSU, Tokyo (JP); Kouichi USHIJIMA, Fukuoka-shi (JP)

(21) Appl. No.: 13/928,114

(22) Filed: Jun. 26, 2013

(30) Foreign Application Priority Data
Sep. 13, 2012 (JP) 2012-201765

(51) Int. Cl. H01L 23/34; H01L 21/50

(52) U.S. Cl. CPC H01L 23/345; H01L 21/50
USPC 257/706; 438/122

(57) ABSTRACT

A power semiconductor element, a high-voltage electrode electrically connected to the power semiconductor element, a heat radiating plate connected to the power semiconductor element and having heat radiation property, a cooling element connected to the heat radiating plate with an insulating film being interposed, and a seal covering the power semiconductor element, a part of the high-voltage electrode, the heat radiating plate, the insulating film, and a part of the cooling element are included. The cooling element includes a base portion of which part is embedded in the seal and a cooling member connected to the base portion. The base portion and the cooling member are separate from each other, and the cooling member is fixed to the base portion exposed through the seal.

### BACKGROUND OF THE INVENTION

1. Field of the Invention

The present invention relates to a power semiconductor device and a method of manufacturing the same, and particularly to a power semiconductor device capable of achieving excellent workability and a method of manufacturing the same.

2. Description of the Background Art

In general, in order to physically and chemically protect a power semiconductor element, a power semiconductor element is resin-sealed as it is placed together with a lead frame serving for electrical connection with the outside, a wire for electrically connecting the lead frame and the semiconductor element to each other, and the like on a cooling device for quickly radiating heat generated by the power semiconductor element during operation.

In order to enhance cooling performance, a cooling device having heat radiating fins in a surface opposed to a surface on which a power semiconductor element is placed has been proposed as a cooling device. For example, Japanese Patent Laying-Open No. 2007-184315 and Japanese Patent Laying-Open No. 2009-295808 have shown a semiconductor module including a cooling device having heat radiating fins.

### SUMMARY OF THE INVENTION

In a conventional power semiconductor device including a cooling device having heat radiating fins, however, a cooling device for the power semiconductor device is formed before a resin-sealing step, and hence an assembly step following the resin-sealing step has had to be performed with the cooling device having been provided. Consequently, workability in steps following the resin-sealing step is impaired by the heat radiating fins exposed like protrusions. For example, handleability of the power semiconductor device in the step following resin-sealing is lowered by the heat radiating fins protruding from the surface opposed to the surface on which the power semiconductor element is placed.

The present invention was made to solve the problems as described above. A primary object of the present invention is to provide a power semiconductor device capable of achieving improved workability of a power semiconductor device and a method of manufacturing the same.

A power semiconductor device according to the present invention includes a power semiconductor element, a high-voltage electrode electrically connected to the power semiconductor element, a heat radiating plate connected to the power semiconductor element and having heat radiation property, a cooling element connected to the heat radiating plate with an insulating film being interposed, and a seal covering the power semiconductor element, a part of the high-voltage electrode, the heat radiating plate, the insulating film, and a part of the cooling element. The cooling element includes a base portion of which part is embedded in the seal and a cooling member connected to the base portion. The base portion and the cooling member are separate from each other, and the cooling member is fixed to the base portion exposed through the seal.

Since the power semiconductor device according to the present invention includes a base portion and a cooling member which are separate from each other, a seal can be formed to cover a power semiconductor element without the cooling member being attached to the base portion. Thus, handleability after the seal for the power semiconductor device is formed can be improved, and workability of the power semiconductor device can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a power semiconductor device in a first embodiment.

FIG. 2 is a schematic cross-sectional view of a power semiconductor device in a second embodiment.

FIG. 3 is a schematic cross-sectional view of a power semiconductor device in a third embodiment.

FIG. 4 is a schematic cross-sectional view of a power semiconductor device in a fourth embodiment.

FIG. 5 is a flowchart showing a method of manufacturing the power semiconductor device in the first embodiment.

FIG. 6 is a flowchart showing a method of manufacturing the power semiconductor device in the fourth embodiment.

### DESCRIPTION OF THE PREFERRED EMBODIMENTS

An embodiment of the present invention will be described hereinafter with reference to the drawings.

### First Embodiment

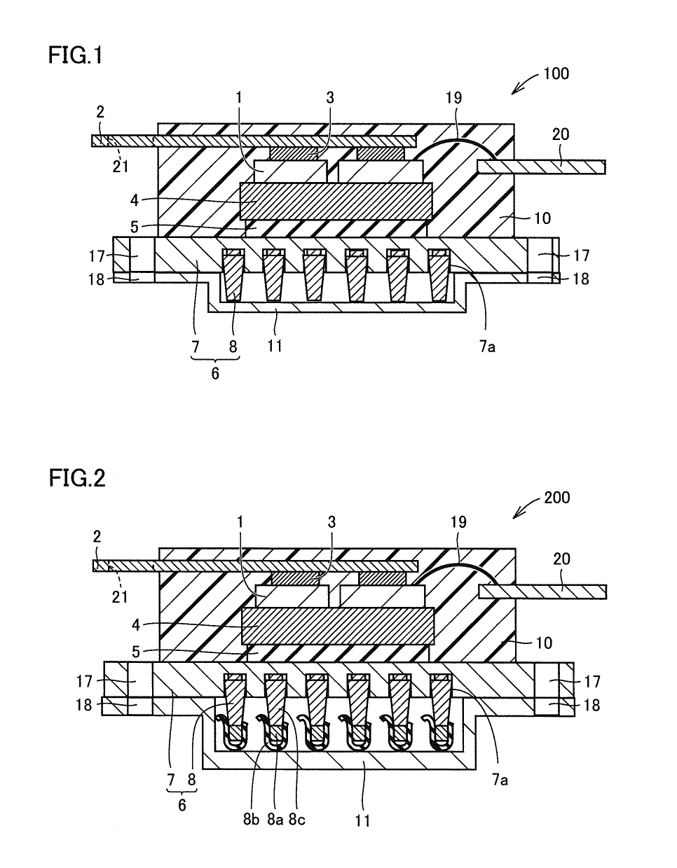

A first embodiment of the present invention will be described with reference to FIG. 1. A power semiconductor device 100 according to the present embodiment includes a power semiconductor element 1, a high-voltage electrode 2 electrically connected to power semiconductor element 1, a heat radiating plate 4 connected to power semiconductor element 1 and having high heat radiation property, a cooling element 6 connected to heat radiating plate 4 with an insulating film 5 being interposed, and a seal 10 covering power semiconductor element 1, heat radiating plate 4, insulating film 5, and a part of cooling element 6.

Power semiconductor element 1 is implemented, for example, by a semiconductor chip having an IGBT (Insulated Gate Bipolar Transistor), an FWD (Free Wheeling Diode), and the like, and it is an element capable of controlling a high current at a high voltage. One main surface of power semiconductor element 1 is electrically connected to high-voltage electrode 2, a signal terminal 20, or the like. For example, high-voltage electrode 2 is electrically connected to power semiconductor element 1 through solder 3, and signal terminal 20 is electrically connected thereto through a wire 19. The other main surface of power semiconductor element 1 is held by heat radiating plate 4 with solder or the like (not shown) being interposed. High-voltage electrode 2 is provided as any structure capable of applying a high voltage to power semiconductor element 1. Since a high current flows through high-voltage electrode 2, high-voltage electrode 2 is connected to the outside through bolt tightening means. Namely, high-voltage electrode 2 includes a through hole 21 for a bolt to pass therethrough.

Heat radiating plate 4 is a heat diffusion plate for diffusing heat generated by power semiconductor element 1 and it is made of a material high in heat radiation property. For example, heat radiating plate 4 should only be composed of copper (Cu), aluminum (Al), or the like. A surface opposed to a surface on which power semiconductor element 1 is mounted is connected to cooling element 6 with insulating film 5 being interposed. Insulating film 5 has electrical insulating property, and it should only be composed, for example, of epoxy resin or the like.

Cooling element 6 includes a base portion 7 and a cooling member 8 which are separate from each other. Base portion 7 and cooling member 8 are connected to each other to thereby form cooling element 6. For example, base portion 7 is a plate-shaped member having a recess 7a and cooling member 8 is a columnar member constructed to fit into recess 7a. A material high in heat radiation property is adopted for base portion 7 and cooling member 8 as in the case of heat radiating plate 4, and for example, they should only be composed of copper, aluminum, or the like. Base portion 7 and cooling member 8 may be made of the same material or of different materials.

Seal 10 seals power semiconductor element 1, high-voltage electrode 2, heat radiating plate 4, insulating film 5, and cooling element 6. Seal 10 has electrical insulating property, and it should only be composed, for example, of epoxy resin or the like. Here, a part of high-voltage electrode 2, a part of signal terminal 20, and a part of cooling element 6 are exposed through seal 10. The part of cooling element 6 exposed through seal 10 includes one surface of base portion 7 having recess 7a and cooling member 8. One surface of base portion 7 having recess 7a is preferably a surface planarized to such an extent that power semiconductor device 100 is stable when power semiconductor device 100 is placed on a flat surface with the surface and the flat surface facing each other.

In addition, cooling element 6 is provided such that cooling element 6 and a cover member 11 are connected to each other to thereby form a cooler. Namely, in power semiconductor device 100 in the present embodiment, heat generated as a result of drive of power semiconductor element 1 efficiently propagates mainly from the semiconductor element to heat radiating plate 4, insulating film 5, and cooling element 6 and is exhausted to the cooler. Here, cooling member 8 is provided in a region surrounded by base portion 7 and cover member 11. The region surrounded by base portion 7 and cover member 11 is preferably constructed such that a coolant can flow therein. Thus, heat which propagated from power semiconductor element 1 to cooling element 6 is radiated from base portion 7 and cooling member 8 to the coolant and cover member 11. At least one of base portion 7 and cooling member 8 is preferably constructed such that an area of contact with the coolant and cover member 11 is great. More preferably, cooling member 8 is constructed to be in contact with the surface of cover member 11 which is opposed to recess 7a. Thus, heat which propagated from power semiconductor element 1 to cooling member 8 is radiated to the coolant and cover member 11.

When the cooler is constructed by connecting cooling element 6 and cover member 11 to each other, base portion 7 and cover member 11 are fixed to each other, for example, by fastening with a bolt and a nut. In this case, through holes 17, 18 are provided in base portion 7 and cover member 11, respectively, and seal 10 does not provide seal over through hole 17 in base portion 7. A nut is arranged above through hole 17 in base portion 7 and a bolt which is inserted from the side of cover member 11 through cover member 11 into through hole 17 in base portion 7 is fastened to the nut, so that power semiconductor device 100 including the cooler can be constructed.

It is noted that, when power semiconductor device 100 is viewed from above, through hole 21 in high-voltage electrode 2 described above is provided not to overlap with through holes 17, 18 in base portion 7 and cover member 11. Specifically, through holes 17, 18 are provided in respective corner portions in a case where a geometry of each of base portion 7 and cover member 11 is rectangular. On the other hand, in a case where a plurality of high-voltage electrodes 2 are formed perpendicularly to a side lying between adjacent corner portions, a plurality of through holes 21 in high-voltage electrode 2 are provided along the side.

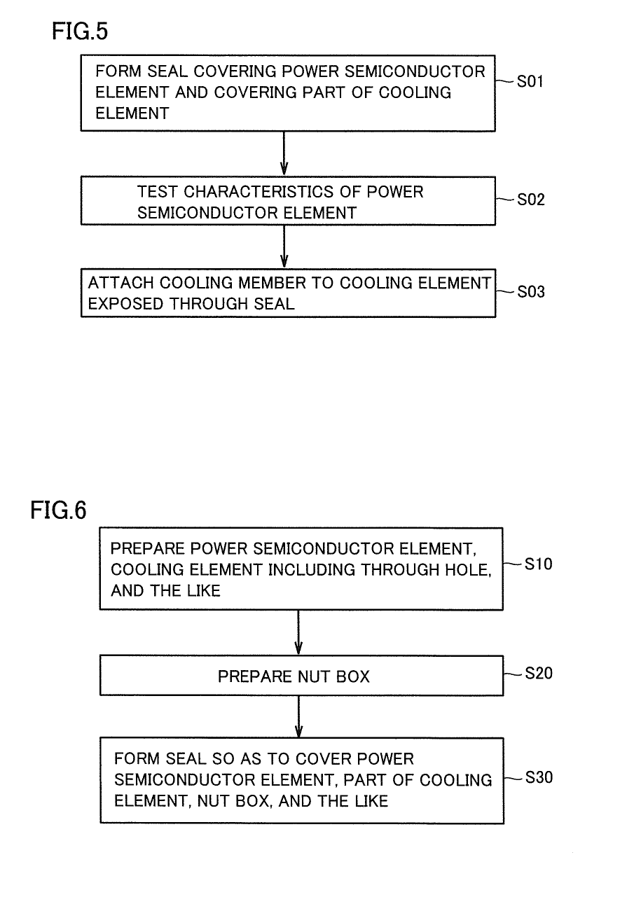

A method of manufacturing power semiconductor device 100 according to the present embodiment will now be described. Referring to FIG. 5, the method of manufacturing power semiconductor device 100 according to the present embodiment includes the steps of forming seal 10 covering power semiconductor element 1 and a part of cooling element 6 cooling power semiconductor element 1 (S01) and attaching cooling member 8 to cooling element 6 exposed through seal 10 (S03).

Initially, in the step (S01), by forming seal 10 so as to cover power semiconductor element 1 and a part of cooling element 6, power semiconductor device 100 sealed with resin or the like while it is connected to cooling element 6 is obtained. Here, the part of cooling element 6 refers to one surface of base portion 7, and in the present step (S01), cooling member 8 has not yet been connected to base portion 7. In addition to power semiconductor element 1 and cooling element 6, high-voltage electrode 2 electrically connected to power semiconductor element 1 and signal terminal 20, heat radiating plate 4 connected to power semiconductor element 1 and having high heat radiation property, and insulating film 5 insulating heat radiating plate 4 from cooling element 6 may be sealed. Here, as described above, a part of high-voltage electrode 2 and one surface of base portion 7 are exposed through seal 10.

Then, in the step (S02), a characteristic test of power semiconductor element 1 is conducted. In this step (S02), for example, electrical characteristics and reliability of power semiconductor element 1 are tested. Here, cooling member 8 has not yet been provided in base portion 7 of power semiconductor device 100.

Then, in the step (S03), cooling member 8 is attached to base portion 7 exposed through seal 10 to thereby form cooling element 6. For example, in a case where recess 7a is formed in base portion 7 on the side opposed to cover member 11 as described above, cooling member 8 may be fitted into recess 7a. Here, cooling member 8 is fitted into recess 7a in base portion 7 so as not to apply load to power semiconductor device 100. In particular, since crack or the like is likely in insulating film 5 when pressure is applied thereto, cooling member 8 is attached to base portion 7 so as not to apply strong vibration or the like. By thus performing the step (S01) to the step (S03) above, the method of manufacturing power semiconductor device 100 in the present embodiment is completed.

As described above, according to the present embodiment, since power semiconductor device 100 includes cooling element 6 formed of base portion 7 and cooling member 8 which are separate from each other, base portion 7 and cooling member 8 are formed as cooling element 6 for power semiconductor device 100 through a process including the step (S01) and the step (S03) in the method of manufacturing power semiconductor device 100. Namely, after power semiconductor device 100 including base portion 7 is sealed in the step (S01), cooling member 8 can be attached to one surface of base portion 7 exposed through seal 10 to thereby form cooling element 6 in the step (S03). Consequently, since one surface of base portion 7 exposed through seal 10 is flat until cooling member 8 is attached, handleability or the like can be improved as compared with the conventional method of manufacturing power semiconductor device 100. Therefore, according to the present embodiment, workability after power semiconductor device 100 is sealed with seal 10 can be improved.

In the present embodiment, as described above, though cooling element 6 may be constituted of base portion 7 having recess 7a and cooling member 8 fitted into recess 7a, cooling element 6 is not limited thereto. For example, it may be constituted of plate-shaped base portion 7 and cooling member 8 bonded to base portion 7 with an adhesive or the like. So long as characteristics of power semiconductor device 100 are not affected, cooling element 6 can be formed by connecting base portion 7 and cooling member 8 to each other with any method.

In addition, in the present embodiment, insulating film 5 and seal 10 may have rigidity to such an extent that they do not deform when base portion 7 and cooling member 8 are connected to each other. Thus, even when force is applied to the inside of power semiconductor device 100 through base portion 7 in the step (S03), deformation of or damage to insulating film 5 and seal 10 can be suppressed and leakage from heat radiating plate 4 and base portion 7 or the like can be prevented.

Moreover, in the present embodiment, high-voltage electrode 2 is connected to the outside through tightening of a bolt as described above. A nut to which the bolt is secured at this time may be provided as a nut box. Specifically, a nut box may be provided in a region between high-voltage electrode 2 and base portion 7. The nut box has a hollow structure, contains a fixed nut therein, and has an opening on a nut side. In this case, in the step (S01), the nut box is sealed with seal 10 while it is arranged in the region between high-voltage electrode 2 and base portion 7. Thus, since seal 10 covers the nut box therearound, the region between high-voltage electrode 2 and base portion 7 can also be sealed with seal 10. By doing so, in the step (S01), such control as not to form seal 10 in the region between high-voltage electrode 2 and base portion 7 is no longer necessary, and workability of a power semiconductor device can further be improved. Here, the bolt is inserted from the side of high-voltage electrode 2 through the through hole provided in high-voltage electrode 2 and the opening in the nut box and fastened to the nut in the nut box, so that high-voltage electrode 2 can electrically be connected to the outside.

### Second Embodiment

A power semiconductor device 200 and a method of manufacturing the same according to a second embodiment of the present invention will be described hereinafter with reference to FIG. 2. Though power semiconductor device 200 and the method of manufacturing the same according to the present embodiment basically include the features the same as those in power semiconductor device 100 and the method of manufacturing the same according to the first embodiment, difference from power semiconductor device 100 according to the first embodiment resides in that cooling member 8 has an elastic portion 8a having elasticity. In the present embodiment, cooling member 8 has a root portion 8c fitted into recess 7a in base portion 7 at one end portion and elastic portion 8a at the other end portion and is constructed to abut to cover member 11 at a contact pressure. By doing so, even in a case where a distance between base portion 7 and cover member 11 opposed to base portion 7 or a length of cooling member 8 is slightly varied, cooling member 8 can be in contact with cover member 11. Consequently, an effect the same as in the first embodiment can be obtained and performance in cooling of the power semiconductor device can be improved.

In the present embodiment, though abutment to cover member 11 may be achieved by elastic portion 8a as described above, abutment is not limited thereto. For example, elastic portion 8a may be covered with a cover 8b high in heat conductivity and cover 8b may abut to cover member 11. Here, cover 8b is connected also to root portion 8c, so that a heat path from root portion 8c through cover 8b to cover member 11 can be formed. Thus, heat conduction to the coolant and cover member 11 can be enhanced and cooling performance of the cooling element can be improved. In addition, by narrowing a region between adjacent cooling members 8 by means of cover 8b, the coolant can efficiently flow between cooling portions 8 and cooling performance can be enhanced.

### Third Embodiment

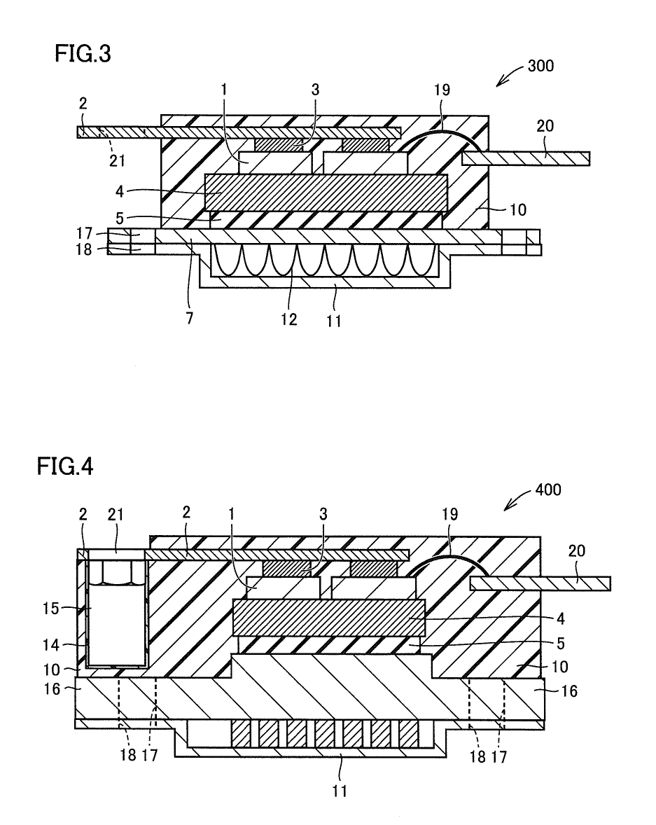

A power semiconductor device 300 and a method of manufacturing the same according to a third embodiment of the present invention will be described hereinafter with reference to FIG. 3. Though power semiconductor device 300 and the method of manufacturing the same according to the present embodiment basically include the features the same as those in power semiconductor device 100 and the method of manufacturing the same according to the first embodiment, they are different from power semiconductor device 100 and the method of manufacturing the same according to the first embodiment in that the cooling member includes a metal tape 12. In the present embodiment, metal tape 12 is ultrasonically bonded to base portion 7 in the step (S03) so as to form a space where a coolant can flow between metal tape 12 and base portion 7. Here, insulating film 5 and seal 10 should only have rigidity to such an extent that they do not deform due to vibration or the like caused during ultrasonic bonding. By doing so, an area of contact between the cooling member and the coolant can be increased. In addition, a material high in heat radiation property may be adopted for metal tape 12, and for example, Al may be adopted. Consequently, an effect the same as in the first embodiment can be obtained and performance in cooling of power semiconductor device 300 can be improved. Metal tape 12 is preferably provided such that it is bonded to base portion 7 at a plurality of locations and it extends perpendicularly to a direction in which the coolant can flow. Thus, an area of contact between metal tape 12 and the coolant can be increased, and performance in cooling of power semiconductor device 300 can be improved. More preferably, metal tape 12 is provided to be in contact with cover member 11. Thus, an area of contact of metal tape 12 with the coolant and cover member 11 can be increased and performance in cooling of power semiconductor device 300 can further be improved.

In the present embodiment, though the cooling member may include metal tape 12 as described above, the cooling member is not limited thereto. The cooling member may include a metal wire or the like so long as it is bonded to base portion 7 so as to form a space between the metal wire or the like and base portion 7 where a coolant can flow. By doing so as well, an area of contact between the cooling member and the coolant can be increased.

### Fourth Embodiment

Though an embodiment in which a cooling member and a base portion are formed as separate components has been discussed in the embodiments described above, an example where a cooling member and a base portion are integrally formed will be described in an embodiment below.

According to the conventional technique, in attaching a power semiconductor device including a cooling device to a cooler, in order to suppress deterioration over time of fastening force and to suppress increase in size of a power semiconductor device, Japanese Patent Laying-Open No. 2007-184315 has proposed a semiconductor module in which a resin-sealed region is limited so as not to seal a bolt tightening portion. In addition, since a high current flows through a high-voltage electrode, the high-voltage electrode should be connected to an external terminal by securing a bolt and a nut to each other. Here, control should be carried out not to allow introduction of resin into a region between the high-voltage electrode and the cooling device where a bolt-nut fastening portion is formed. Workability in the step of resin-sealing a power semiconductor device is thus impaired. A power semiconductor device and a method of manufacturing the same in the present embodiment are proposed to solve the problems as described above.

A power semiconductor device according to the present embodiment includes a power semiconductor element, a high-voltage electrode electrically connected to the power semiconductor element, a heat radiating plate connected to the power semiconductor element and having heat radiation property, a cooling element connected to the heat radiating plate with an insulating film being interposed, a nut box located in a region between the high-voltage electrode and the cooling element, and a seal covering the power semiconductor element, a part of the high-voltage electrode, the heat radiating plate, the insulating film, a part of the cooling element, and the nut box, the nut box includes a nut and has an opening on a side where it comes in contact with high-voltage electrode 2, a base portion of the cooling element includes a through hole, and the nut and the opening are located above the through hole.

According to the power semiconductor device and the method of manufacturing the same in the present embodiment, since the seal is formed such that the nut box is arranged between the high-voltage electrode and the cooling element and above the through hole in the cooling element, control for preventing introduction of resin into the region located between the high-voltage electrode and the cooling element and above the through hole in the cooling element is unnecessary. Consequently, workability of a power semiconductor device can be improved.

A power semiconductor device 400 and a method of manufacturing the same in a fourth embodiment of the present invention will specifically be described hereinafter with reference to FIG. 4. FIG. 4 is a schematic cross-sectional view of power semiconductor device 400 of a type having nut box 14. Power semiconductor device 400 according to the present embodiment includes power semiconductor element 1, high-voltage electrode 2 electrically connected to power semiconductor element 1, heat radiating plate 4 connected to power semiconductor element 1 and having high heat radiation property, a cooling element 16 connected to heat radiating plate 4 with insulating film 5 being interposed, nut box 14 located in a region between high-voltage electrode 2 and cooling element 16, and seal 10 covering power semiconductor element 1, a part of high-voltage electrode 2, heat radiating plate 4, insulating film 5, a part of cooling element 16, and nut box 14, as described above.

Power semiconductor element 1 is implemented, for example, by a semiconductor chip having an IGBT (Insulated Gate Bipolar Transistor), an FWD (Free Wheeling Diode), and the like. One main surface of power semiconductor element 1 is electrically connected to high-voltage electrode 2, signal terminal 20, or the like. For example, high-voltage electrode 2 is electrically connected to power semiconductor element 1 through solder or the like, and signal terminal 20 is electrically connected thereto through wire bonding or the like. The other main surface of power semiconductor element 1 is held by heat radiating plate 4 with solder or the like (not shown) being interposed. High-voltage electrode 2 is provided as any structure capable of applying a high voltage to power semiconductor element 1. Since a high current flows through high-voltage electrode 2, high-voltage electrode 2 is connected to the outside through bolt tightening means. Namely, high-voltage electrode 2 includes through hole 21 for a bolt to pass therethrough.

Heat radiating plate 4 is a heat diffusion plate for diffusing heat generated by power semiconductor element 1 and it is made of a material high in heat radiation property. For example, heat radiating plate 4 should only be composed of copper (Cu), aluminum (Al), or the like. A surface opposed to a surface on which power semiconductor element 1 is mounted is connected to cooling element 16 with insulating film 5 being interposed.

Insulating film 5 has electrical insulating property, and it should only be composed, for example, of epoxy resin or the like.

Cooling element 16 is provided such that cooling element 16 and cover member 11 are connected to each other to thereby form a cooler. Namely, in power semiconductor device 400 in the present embodiment, heat generated as a result of drive of power semiconductor element 1 efficiently propagates mainly from the semiconductor element to heat radiating plate 4, insulating film 5, and cooling element 16 and is radiated.

In the present embodiment, cooling element 16 includes base portion 7 and cooling member 8 which are integrated with each other. A material high in heat radiation property is adopted for cooling element 16 as in the case of heat radiating plate 4, and for example, it should only be composed of copper, aluminum, or the like. Base portion 7 and cooling member 8 may be made of the same material or of different materials.

Moreover, cooling element 16 is provided such that cooling element 16 and cover member 11 are connected to each other to thereby form a cooler. Namely, in power semiconductor device 400 in the present embodiment, heat generated as a result of drive of power semiconductor element 1 efficiently propagates mainly from the semiconductor element to heat radiating plate 4, insulating film 5, and cooling element 16 and is exhausted to the cooler.

When the cooler is constructed by connecting cooling element 16 and cover member 11 to each other, for example, through holes 17, 18 are provided in base portion 7 and cover member 11, respectively, and base portion 7 and cover member 11 are fixed to each other by fastening with a bolt and a nut. Power semiconductor device 400 including the cooler can thus be constructed. It is noted that, when power semiconductor device 400 is viewed from above, through hole 21 in high-voltage electrode 2 described above is provided not to overlap with through holes 17, 18 in base portion 7 and cover member 11. Through holes 17, 18 are provided in respective corner portions in a case where a geometry of each of base portion 7 and cover member 11 is rectangular. On the other hand, in a case where a plurality of high-voltage electrodes 2 are formed perpendicularly to a side lying between adjacent corner portions, a plurality of through holes 21 in high-voltage electrode 2 are provided along the side.

High-voltage electrode 2 and an external terminal are connected to each other by securing a bolt and nut 15 to each other. Nut 15 is provided in such a state as being housed in nut box 14. Nut box 14 has a hollow structure, contains fixed nut 15 therein, and has an opening on a side of nut 15. Nut box 14 is provided such that it is located in the region between high-voltage electrode 2 and cooling element 16 (base portion 7) and the opening is located under through hole 21 in high-voltage electrode 2. Here, seal 10 covers nut box 14 therearound except for the opening. The bolt is inserted from the side of high-voltage electrode 2 through through hole 21 in high-voltage electrode 2 and the opening in nut box 14 and fastened to nut 15 in nut box 14, so that high-voltage electrode 2 can electrically be connected to the outside.

Seal 10 seals power semiconductor element 1, high-voltage electrode 2, signal terminal 20, heat radiating plate 4, insulating film 5, cooling element 16, and nut box 14. Seal 10 has electrical insulating property, and it should only be composed, for example, of epoxy resin or the like. Here, a part of high-voltage electrode 2, a part of signal terminal 20, and a part of cooling element 16 are exposed through seal 10. It is noted that, in the present embodiment as well, seal 10 does not provide seal over through hole 17, 18. Since high-voltage electrode 2 is not provided above through hole 17, 18, workability of power semiconductor device 400 is not impaired even in a case of forming seal 10 such that seal 10 does not provide seal over through hole 17, 18. On the other hand, in a case of forming seal 10 so as not to seal with seal 10, the region between high-voltage electrode 2 and cooling element 16 shown in FIG. 4, workability of power semiconductor device 400 is impaired. Therefore, by providing nut box 14 as shown in FIG. 4, covering with seal 10 can be achieved and workability can be improved.

The method of manufacturing power semiconductor device 400 according to the present embodiment will now be described. Referring to FIG. 6, the method of manufacturing power semiconductor device 400 according to the present embodiment includes the steps of preparing power semiconductor element 1, high-voltage electrode 2 electrically connected to power semiconductor element 1 and including through hole 21, heat radiating plate 4 connected to power semiconductor element 1 and having heat radiation property, and cooling element 16 connected to heat radiating plate 4 with insulating film 5 being interposed (S10), preparing nut box 14 having a hollow structure, containing nut 15 therein, and having an opening (S20), and forming seal 10 covering power semiconductor element 1, a part of high-voltage electrode 2, heat radiating plate 4, insulating film 5, a part of cooling element 16, and nut box 14 by arranging nut box 14 in a region between high-voltage electrode 2 and cooling element 16 such that the opening is located under the through hole in high-voltage electrode 2 (S30).

Initially, in the step (S10), by preparing power semiconductor element 1, high-voltage electrode 2 electrically connected to power semiconductor element 1 and including through hole 21, heat radiating plate 4 connected to power semiconductor element 1 and having heat radiation property, and cooling element 16 connected to heat radiating plate 4 with insulating film 5 being interposed, power semiconductor device 400 not sealed with seal 10 while it is connected to cooling element 16 is obtained.

Then, in the step (S20), nut box 14 is prepared. Nut box 14 can have any shape so long as a nut box has a hollow structure, contains nut 15 therein, and has an opening.

Then, in the step (S30), seal 10 is formed in power semiconductor device 400. In this step (S30), nut box 14 is arranged in the region between high-voltage electrode 2 and cooling element 16 such that the opening is located above through hole 17 in base portion 7 of power semiconductor device 400, so that seal 10 covering a part of high-voltage electrode 2, heat radiating plate 4, insulating film 5, a part of cooling element 16, and nut box 14 is formed. Thus, seal 10 can cover nut box 14 therearound except for the opening. By doing so, as compared with the conventional method of manufacturing a power semiconductor device which has had to be devised such that resin is prevented from flowing into the region between high-voltage electrode 2 and cooling element 16 which is a portion located under the through hole in high-voltage electrode 2, formation of seal 10 can be facilitated and workability can be improved.

As described above, according to the present embodiment, in providing a fixing member for connecting and fixing high-voltage electrode 2 and an external terminal to each other in the region between high-voltage electrode 2 and cooling element 16, sealing is carried out after nut box 14 prepared in advance is positioned, so that the fixing member can be formed without formation of seal 10 being restricted. Therefore, workability of power semiconductor device 400 can be improved.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A power semiconductor device, comprising:
a power semiconductor element;
a high-voltage electrode electrically connected to said power semiconductor element;
a heat radiating plate connected to said power semiconductor element and having heat radiation property;
a cooling element connected to said heat radiating plate with an insulating film being interposed; and
a seal covering said power semiconductor element, a part of said high-voltage electrode, said heat radiating plate, said insulating film, and a part of said cooling element,
said cooling element including a base portion of which part is embedded in said seal and a cooling member connected to said base portion, and
said base portion and said cooling member being separate from each other, and said cooling member being fixed to said base portion exposed through said seal.

2. The power semiconductor device according to claim 1, wherein
said base portion has a recess, and
said cooling member is fitted into said recess.

3. The power semiconductor device according to claim 2, wherein
said cooling member has a root portion fitted into said recess at its one end portion and an elastic portion having elasticity at the other end portion, and
said power semiconductor device comprises a cover member provided to be in contact with said elastic portion.

4. The power semiconductor device according to claim 1, wherein
said cooling member is bonded to said base portion so as to form a space between said cooling member and said base portion, through which a coolant can flow.

5. The power semiconductor device according to claim 4, wherein
said cooling member includes a metal tape, and
said metal tape extends perpendicularly to a direction in which said coolant can flow.

6. The power semiconductor device according to claim 5, comprising a cover member provided to be in contact with said cooling member.

7. The power semiconductor device according to claim 1, further comprising a nut box in a region between said high-voltage electrode and said cooling element, wherein
said nut box includes a nut and has an opening,
said nut and said opening are located under said high-voltage electrode, and
said seal covers said region other than said nut box.

8. A power semiconductor device, comprising:
a power semiconductor element;
a high-voltage electrode electrically connected to said power semiconductor element;
a heat radiating plate connected to said power semiconductor element and having heat radiation property;
a cooling element connected to said heat radiating plate with an insulating film being interposed;
a nut box located in a region between said high-voltage electrode and said cooling element; and
a seal covering said power semiconductor element, a part of said high-voltage electrode, said heat radiating plate, said insulating film, a part of said cooling element, and said nut box,
said high-voltage electrode including a through hole, and
said nut box including a nut and having an opening on a side where it comes in contact with said high-voltage electrode, and said nut and said opening being located under said through hole.

9. A method of manufacturing a power semiconductor device, comprising the steps of:
forming a seal covering a power semiconductor element and a part of a cooling element cooling said power semiconductor element; and
attaching a cooling member to said cooling element exposed through said seal.

10. The method of manufacturing a power semiconductor device according to claim 9, wherein
said power semiconductor element is tested before said cooling member is attached to said cooling element.

11. A method of manufacturing a power semiconductor device, comprising the steps of:
preparing a power semiconductor element, a high-voltage electrode electrically connected to said power semiconductor element and including a through hole, a heat radiating plate connected to said power semiconductor element and having heat radiation property, and a cooling element connected to said heat radiating plate with an insulating film being interposed;
preparing a nut box having a hollow structure, containing a nut therein, and having an opening; and
forming a seal covering said power semiconductor element, a part of said high-voltage electrode, said heat radiating plate, said insulating film, a part of said cooling element, and said nut box by arranging said nut box in a region between said high-voltage electrode and said cooling element such that said opening is located under said through hole.
